(19) United States
(12) Patent Application Publication
(10) Pub. No.: US 2017/0217086 A1
(43) Pub. Date: Aug. 3, 2017

(54) SEAMLESS HOUSING

(71) Applicant: XAVi Technologies Corp., New Taipei City (TW)

(72) Inventor: Cheng-Ming FAN, New Taipei City (TW)

(21) Appl. No.: 15/135,572

(22) Filed: Apr. 22, 2016

(30) Foreign Application Priority Data
Jan. 28, 2016 (TW) 105201318

(51) Int. Cl. B29C 65/00; H05K 5/03; H05K 5/02; B29C 65/08

(52) U.S. Cl. CPC B29C 66/126; B29C 65/08; H05K 5/03; H05K 5/0217; B29L 2031/3481

(57) ABSTRACT

A seamless housing includes a first cover and a second cover. The first cover has a first outer surface. The first outer surface has a first outer edge. The second cover covers to the first cover and has a second outer surface. The second outer surface has a second outer edge. The first outer edge and the second outer edge coincide. The first outer surface and the second outer surface form a corner at the junction of the first outer edge and the second outer edge.

### RELATED APPLICATIONS

This application claims priority to Taiwan Application Serial Number 105201318, filed Jan. 28, 2016, which is herein incorporated by reference.

### BACKGROUND

Technical Field

The present disclosure relates to a seamless housing.

Description of Related Art

Recently, many parts of common consumer electronic products (e.g., mobile phones computers, digital cameras, etc.) on the market are made of plastic. In order to reduce costs and make the products thinner, plastic parts are mostly connected to each other by way of heat welding.

The principle of the ultrasonic welding technology is basically a manufacturing method of converting sounds into thermal energy. For example, an ultrasonic machine can generate high frequency signals of 20 KHz or 15 KHz. By using an energy converting horn on the ultrasonic machine to directly contact plastic parts, molecules of the plastic parts dramatically rub and thus generate a high local temperature. The plastic parts will melt when the temperature is greater than the melting point of the plastic parts. After cooling, the molten plastic parts will solidify again and achieve a welding effect.

In general, the appearances of products assembled by using the ultrasonic welding technology often use fused seams to decorate defects and gaps after assembled. However, the fused seams will obviously make users notice that the products are assembled from a plurality of components, and thus cannot provide a visual experience of one-piece appearance after being assembled for the users. If the fused seams appear on some high-end electronic products, it is likely to make users feel that the products are cheap.

Accordingly, how to provide a housing design to solve the aforementioned problems becomes an important issue to be solved by those in the industry.

### SUMMARY

Accordingly, an aspect of the disclosure is to provide a seamless housing that can provide a visual experience of a one-piece appearance after assembled.

According to an embodiment of the disclosure, the seamless housing includes a first cover and a second cover. The first cover has a first outer surface. The first outer surface has a first outer edge. The second cover covers to the first cover and has a second outer surface. The second outer surface has a second outer edge. The first outer edge and the second outer edge coincide. The first outer surface and the second outer surface form a corner at the junction of the first outer edge and the second outer edge.

In an embodiment of the disclosure, the first cover has an opening adjacent to the first outer edge. The second cover covers the opening. The corner has a shape of a right angle.

In an embodiment of the disclosure, the first cover has a retaining surface at the opening. The second cover has an abutting surface connected to the second outer edge. The abutting surface at least partially abuts against the retaining surface.

In an embodiment of the disclosure, the abutting surface completely abuts against the retaining surface.

In an embodiment of the disclosure, the retaining surface is an inclined surface. An angle formed between the first outer surface and the retaining surface is substantially in a range from 30 to 60 degrees.

In an embodiment of the disclosure, the abutting surface is an inclined surface. An angle formed between the second outer surface and the abutting surface is substantially in a range from 30 to 60 degrees.

In an embodiment of the disclosure, both the retaining surface and the abutting surface are ring-shaped. The abutting surface is surrounded and retained at an inner side of the retaining surface.

In an embodiment of the disclosure, the first cover further has a first welding surface located in the opening. The second cover further has a second welding surface facing the first welding surface. The seamless housing further includes at least one welding. The welding line is connected between the first welding surface and the second welding surface.

In an embodiment of the disclosure, the first cover includes a plurality of abutting blocks disposed on the first welding surface. The abutting blocks abut against the second welding surface.

In an embodiment of the disclosure, the second cover has a plurality of ribs. The ribs abut against an inner all of the first cover in the opening.

Accordingly, in the seamless housing of the disclosure, the junction of the first cover and the second cover after assembled is designed at the corner of the seamless housing, so the junction is not easily discovered by users, which makes the seamless housing achieve the purpose of providing a visual experience of a one-piece appearance to the users. The retaining surface connected to the first outer edge of the first cover is used to abut against and retain the abutting surface connected to the second outer edge of the second cover, such that the first outer edge of the first cover and the second outer edge of the second cover can easily align and coincide with each other. Furthermore, in order to effectively improve the alignment accuracy between the first outer edge and the second outer edge, the ribs can be disposed on the second cover to abut against the inner wall of the first cover. In addition, the abutting blocks are disposed the welding surfaces of the first covet and the second cover, so as to prevent the situation that the first outer edge and the second outer edge can not accurately align and coincide with each other because a minimum relative distance of the first cover and the second cover can not be kept during assembly process.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a perspective view of a seamless housing according to an embodiment of the disclosure;

FIG. 2 is an exploded view of the seamless housing according to an embodiment of the disclosure;

FIG. 3 is a partial cross-sectional view of the seamless housing taken along line 3-3 in FIGS. 1; and

FIG. 4 is a partial cross-section a view of the seamless housing taken along line 4-4 in FIG. 1.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

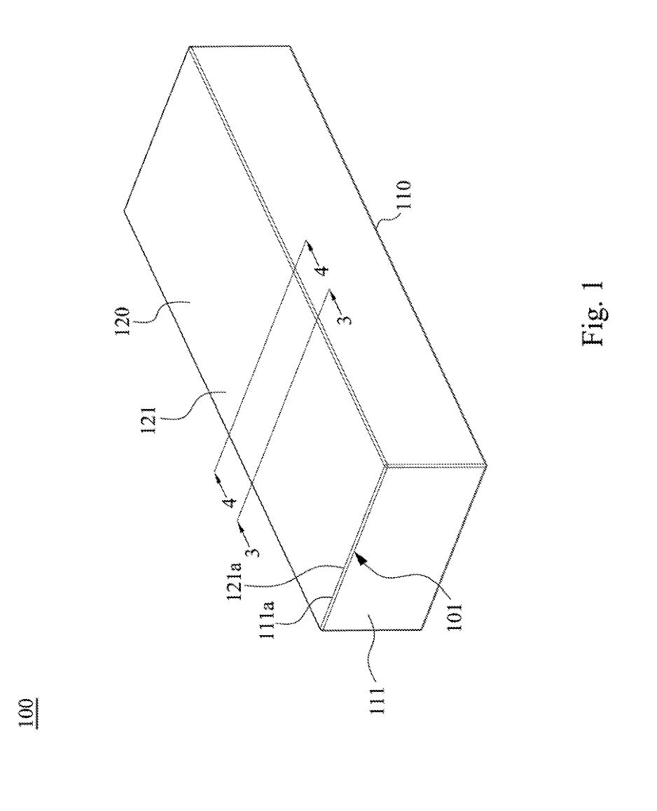

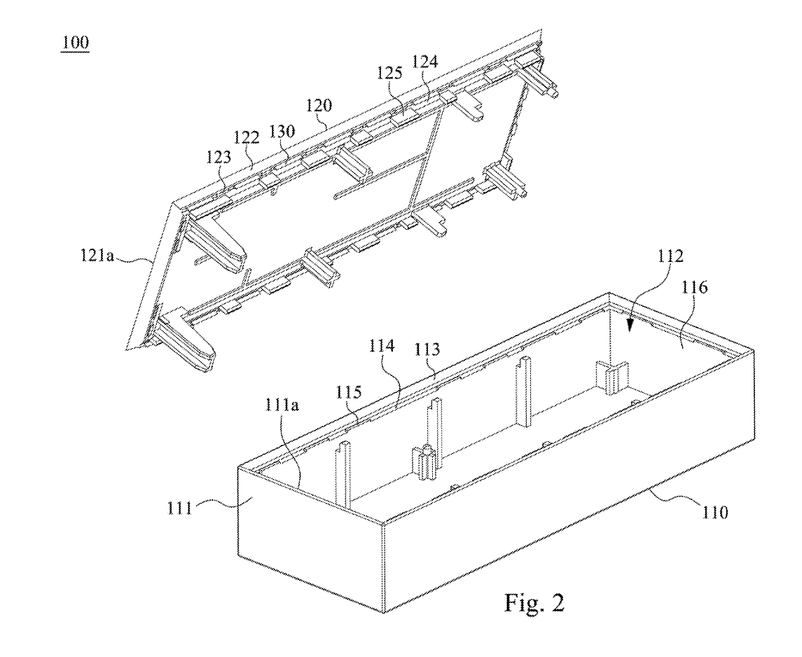

Reference is made to FIG. 1 and FIG. 2. FIG. 1 is a perspective view of a seamless housing according to an embodiment of the disclosure. FIG. 2 is an exploded view of the seamless housing according to an embodiment of the disclosure. As shown in FIG. 1 and FIG. 2, in the present embodiment, the seamless housing 100 includes a first cover 110 and a second cover 120. The first cover 110 has a first outer surface 111. The first outer surface 111 has a first outer edge 111a. The second cover 120 has a second outer surface 121.

The second outer surface 121 has a second outer edge 121a. As a specific example, the first cover 110 has an opening 112 adjacent to the first outer edge 111a, and the second cover 120 is configured to cover the opening 112. When the second cover 120 covers the opening 112 of the first cover 110 (referred to FIG. 1), the first outer edge 111a and the second outer edge 112a coincide. The first outer surface 111 and the second outer surface 121 form a corner 101 at the junction of the first outer edge 111a and the second outer edge 121a.

It can be seen that in the seamless housing 100 of the disclosure, the junction of the first cover 110 and the second cover 120 after assembled is designed at the corner 101 of the seamless housing 100, so the junction can be visually hidden by the corner 101 of the seamless housing 100 and thus is not easily discovered by users, so as to achieve the purpose of providing a visual experience of a one-piece appearance to the users.

Furthermore, as shown in FIG. 2, the first cover 110 has a retaining surface 113 at the opening 112. The second cover 120 has an abutting surface 122 connected to the second outer edge 121a. In the instant embodiment, the abutting surface 122 of the second cover 120 completely abuts against the retaining surface 113 of the first cover 110. Hence, when the second cover 120 covers the opening 112 of the first cover 110, the retaining surface 113 can firmly support the abutting surface 122. In addition, in the instant embodiment, both the retaining surface 113 and the abutting surface 122 are ring-shaped, and the abutting surface 122 is surrounded and retained at an inner side of the retaining surface 113. As a specific example, the retaining surface 113 is concave, and the abutting surface 122 is convex.

With the foregoing structural configuration, the first outer edge 111a of the first cover 110 and the second outer edge 121a of the second cover 120 can be easily align and coincide with each other.

Furthermore, as shown in FIG. 2, in the present embodiment, the second cover 120 has an inner surface 124 and a plurality of ribs 125. The inner surface 124 and the second outer surface 121 are respectively located at opposite sides of the second cover 120. The ribs 125 are disposed on the inner surface 124 and substantially arranged along the profile of the second outer edge 121a. The ribs 125 are configured to abut against an inner wall 116 of the first cover 110 in the opening 112. Hence, when the second cover 120 covers the opening 112 of the first cover 110, the ribs 125 can prevent the second cover 120 from horizontally moving relative to the first cover 110, so as to further effectively improve the alignment accuracy between the first outer edge 111a and the second outer edge 121a.

In some embodiments, the abutting surface 122 of the second cover 120 can only partially abut against the retaining surface 113 of the first cover 110.

In some embodiments, the retaining surface 113 of the first cover 110 is an inclined surface. An angle formed between the first outer surface 111 and the retaining surface 113 is substantially in a range from 30 to 60 degrees, but the disclosure is not limited in this regard.

In some embodiments, the abutting surface 122 of the second cover 120 is an inclined surface. An angle formed between the second outer surface 121 and the abutting surface 122 is substantially in a range from 30 to 60 degrees, but the disclosure is not limited in this regard.

In some embodiments, the retaining surface 113 of the first cover 110 and/or the abutting surface 122 of the second cover 120 can be inclined surfaces, curved surfaces, irregular surface, or a combination thereof.

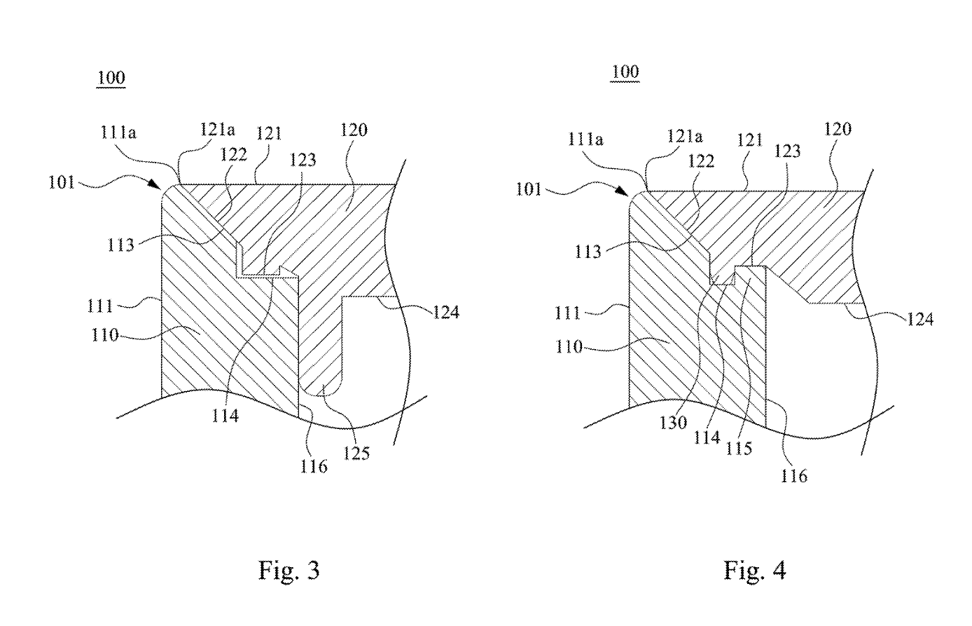

As a specific example, reference is made to FIG. 3, which is a partial cross-sectional view of the seamless housing taken along line 3-3 in FIG. 1. As shown in FIG. 3, in the present embodiment, the corner 101 formed between the first outer surface 111 and the second outer surface 121 has a shape of a right angle (As a specific example, the corner 101 has a round chamfer), the angle formed between the first outer surface 111 and the retaining surface 113 is substantially 45 degrees, and the angle formed between the second outer surface 121 and the abutting surface 122 is substantially 45 degrees. In some embodiments, the first cover 110 and the second cover 120 are made of plastics, so the first cover 110 and the second cover 120 can be easily manufactured under the foregoing angular configuration (because the process yield of the foregoing angular configuration is higher). In some embodiments, the corner 101 can be formed without the round chamfer.

In some embodiments, the first cover 110 and the second cover 120 are made of metals and can be manufactured by various kinds of known manufacturing methods. Hence, first cover 110 and the second cover 120 can be manufactured without the limitation of the foregoing angular configuration.

As shown in FIG. 2 and FIG. 3, in the present embodiment, the, first cover 110 further has a first welding surface 114 located in the opening 112, and the first welding surface 114 is located between the retaining surface 113 and the inner wall 116. The second cover 120 further has a second welding surface 123. When the second cover 120 covers the opening 112 of the first cover 110, the second welding surface 123 faces the first welding surface 114 and is located between the abutting surface 122 and the inner surface 124. That is, both the first welding surface 114 and the second welding surface 123 are ring-shaped. The seamless housing 100 further includes a plurality of welding lines 130. The welding lines 130 are uniformly distributed and connected between the first welding surface 114 and the second welding surface 123 (referred to FIG. 4).

In the assembly processes of the seamless housing 100 of the embodiment, assemblers can use the ultrasonic welding technology to make the molecules of the welding lines 130 dramatically rub and thus generate local high temperature after the second cover 120 is covered the opening 112 of the first cover 110. The welding lines 130 will melt when the temperature is greater than the welding point of the welding lines 130. After cooling the molten welding lines 130 will solidify again and adhere between the first welding surface 114 and the second welding surface 123, so as to achieve the effect of welding the first welding surface 114 and the second welding surface 123.

As shown in FIG. 2, in the present embodiment, the welding lines 130 are manufactured on the second cover 120 in advance, but the disclosure is not limited in this regard. In some embodiments, the welding lines 130 can be manufactured on the first cover 110 in advance.

Reference is made to FIG. 4. FIG. 4 is a partial cross-sectional view of the seamless housing taken along line 4-4 in FIG. 1. As shown in FIG. 2 and FIG. 4 in the present embodiment, the first cover 110 includes a plurality of abutting blocks 115 uniformly distributed and disposed on the first welding surface 114. The abutting blocks 115 a but against the second welding surface 123. Hence, when an ultrasonic welding process is performed to the first cover 110 and the second cover 120 of the seamless housing 100, the abutting blocks 115 can prevent the situation that a minimum relative distance (for avoiding the first welding surface 114 directly contacting the second welding surface 123) of the first cover 110 and the second cover 120 can not be kept during assembly process. Thereby, the first outer edge 111a and the second outer edge 121a can accurately align and coincide with each other.

In some embodiments, abutting blocks can also be uniformly distributed and disposed on the second welding surface 123, arranged with the welding lines 130 in a staggered manner, and configured to abut against the first welding surface 114.

According to the foregoing recitations of the embodiments of the disclosure, it can be seen that in the seamless housing of the disclosure, the junction of the first cover and the second cover after assembled is designed at the corner of the seamless housing, so the junction is not easily discovered by users, which makes the seamless housing achieve the purpose of providing a visual experience of a one-piece appearance to the users. The retaining surface connected to the first outer edge of the first cover is used to abut against and retain the abutting surface connected to the second outer edge of the second cover, such that the first outer edge of the first cover and the second outer edge of the second cover can easily align and coincide with each other. Furthermore, in order to effectively improve the alignment accuracy between the first outer edge and the second outer edge, the ribs can he disposed on the second cover to abut against the inner wall of the first cover. In addition, the abutting blocks are disposed the welding surfaces of the first cover and the second cover, so as to prevent the situation that the first outer edge and the second outer edge can not accurately align and coincide with each other because a minimum relative distance of the first cover and the second cover can not be kept during assembly process.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A seamless housing, comprising:
a first cover having a first outer surface, the first outer surface having a first outer edge; and
a second cover covering the first cover and having a second outer surface, the second outer surface having a second outer edge,
wherein the first outer edge and the second outer edge coincide, and the first outer surface and the second outer surface form a corner at the junction of the first outer edge and the second outer edge.

2. The seamless housing of claim 1, wherein the first cover has an opening adjacent to the first outer edge, the second cover covers the opening, and the corner has a shape of a right angle.

3. The seamless housing of claim 2 wherein the first cover has a retaining surface at the opening, the second cover has an abutting surface connected to the second outer edge, and the abutting surface at least partially abuts against the retaining surface.

4. The seamless housing of claim 3, wherein the abutting surface completely abuts against the retaining surface.

5. The seamless housing of claim 3, wherein the retaining surface is an inclined surface, and an angle formed between the first outer surface and the retaining surface is substantially in a range from 30 to 60 degrees.

6. The seamless housing of claim 3, wherein the abutting surface is an inclined surface, and an angle formed between the second outer surface and the abutting surface is substantially in a range from 30 to 60 degrees.

7. The seamless housing of claim 3, wherein both the retaining surface and the abutting surface are ring-shaped, and the abutting surface is surrounded and retained at an inner side of the retaining surface

8. The seamless housing of claim 3, wherein the first cover further has a first welding surface located in the opening, the second cover further has a second welding surface facing the first welding surface, the seamless housing further comprises at least one welding line, and the welding line is connected between the first welding surface and the second welding surface.

9. The seamless housing of claim 8, wherein the first cover comprises a plurality of abutting blocks disposed on the first welding surface, and the abutting blocks abut against the second welding surface.

10. The seamless housing of claim 2, wherein the second cover has a plurality of ribs, and the ribs abut against an inner wall of the first cover in the opening.
